(19) United States
(12) Patent Application Publication
(10) Pub. No.: US 2008/0122093 A1
(43) Pub. Date: May 29, 2008

(54) SEMICONDUCTOR DEVICE AND METHOD FOR MANUFACTURING THE SAME

(76) Inventor: Sang-Il Hwang, Gangwon-do (KR)

Correspondence Address: SHERR & NOURSE, PLLC, 620 HERNDON PARKWAY, SUITE 200, HERNDON, VA, 20170, US

(21) Appl. No.: 11/933,791

(22) Filed: Nov. 1, 2007

(30) Foreign Application Priority Data
Nov. 27, 2006 (KR) 10-2006-0117380

(51) Int. Cl. H01L 23/52; H01L 21/4763

(52) U.S. Cl. 257/751; 438/626; 257/E23.141; 257/E21.495

(57) ABSTRACT

A semiconductor device and a method for manufacturing the same are provided. The semiconductor device can include a lower metal wiring formed over a semiconductor substrate. A first metal barrier layer can be formed over the lower metal wiring and an interlayer insulating layer formed over the first metal barrier layer. An upper metal wiring can be formed over the interlayer insulating layer. A contact may be formed for electrically connecting the lower metal wiring and the upper metal wiring. A second metal barrier layer pattern having a plurality of holes can be formed over the upper metal wiring and over the interlayer insulating layer. The dielectric constant of the interlayer insulating layer may be further reduced by forming an air gap between the interlayer insulating layer and the second metal barrier layer pattern including the plurality of holes. The air gap can be formed in regions between the interlayer insulating layer and the second metal barrier layer pattern that are not occupied by the upper metal wiring.

The present application claims priority under 35 U.S.C. 119 to Korean Patent Application No. 10-2006-0117380 (filed on Nov. 27, 2006), which is hereby incorporated by reference in its entirety.

### BACKGROUND

Aspects of semiconductor technology have focused on providing multilayer metal wiring structures to semiconductor devices due to a decreased width and pitch of metal wirings. As the pitch of metal wirings has decreased, a resistance-capacitance (RC) delay due to both the dielectric constant of an interlayer insulating layer provided between the metal wirings and the resistance of the wirings has become problematic.

In response to this problem, interlayer insulating layer composed of low-k materials having a dielectric constant lower than that of a silicon oxide (SiO₂) layer have been provided. The use of low-k materials as an interlayer insulating layer between metal wirings may serve to reduce both parasitic capacitance and crosstalk noise between metal wirings, thereby improving the performance of semiconductor devices.

In addition to the use of the low-k material, the structures of the interlayer insulating layer and metal wirings have also become a significant issue in the design of wirings. Until now, it has been commonly known that electromigration caused by collision of electrons is a main factor that contributes to reducing the reliability of metal wirings. However, during operation of the semiconductor device, the reduction in the reliability of metal wirings in a semiconductor device may be more greatly effected by Joule's heat generated by current applied to the metal wirings than by electromigration caused by collision of electrons. Thus, this aspect must been taken into consideration in determining the structures of the low-k interlayer insulating layer and metal wirings when the metal wirings are designed.

A SiO₂ layer formed using a tetra-ethyl-ortho-silicate (TEOS) source has been used as the interlayer insulating layer which fills the gaps between metal wirings at a low temperature for planarization. This SiO₂ layer may have a high deposition rate and may also be highly resistant to cracking. On the other hand, the SiO₂ layer may exhibit poor coating performance for uneven surfaces so that it has limitations in filling any space formed between metal wirings. Thus, after depositing an oxide layer, an organic compound having low viscosity may be formed on and/or over the oxide layer using a spin coating method. Flattening may be done by simultaneously performing deposition and etching using a high density plasma (HDP).

Increase the operating speed of a semiconductor device while also increasing a high integration density has been attempted by applying a low-k insulating layer (k≦3.0), which has been used with copper metal wirings, to multilayer aluminum metal wirings. However, using a low-k thin film may cause problems in that the hardness of a deposited thin film may be reduced due to the decreased dielectric constant of the thin film. This is because the volume of fine pores in the thin film may increase as the dielectric constant of the thin film decreases mainly due to fine pores in it. One such low-k material is black diamond, which has a dielectric constant of about 2.7 to 3. Even the black diamond cannot achieve a lower dielectric constant than that of an ideal low-k material, which is a material having an air gap. However, it is practically difficult to form such an air gap due to structural limitations.

### SUMMARY

Embodiments relate to a semiconductor device and a method for manufacturing the same that reduce RC delay by using a low-k insulating layer having an air-filled space between metal wirings.

Embodiments relate to a method for manufacturing a semiconductor device that can include at least one of the following steps: forming a lower metal wiring over a semiconductor substrate; forming a first metal barrier layer over the lower metal wiring; forming an interlayer insulating layer over the first metal barrier layer; forming a contact extending within the first metal barrier layer and the interlayer insulating layer; forming a negative photoresist over the interlayer insulating layer and the contact; forming a trench in a negative photoresist; forming an upper metal wiring in the trench, wherein the upper metal wiring is electrically connected to the lower metal wiring through the contact; planarizing the entire uppermost surface of the negative photoresist and the upper metal wiring; forming a second metal barrier layer over the negative photoresist and the upper metal wiring; forming a positive photoresist pattern having a plurality of first holes over the second metal barrier layer; forming a second metal barrier layer pattern having a plurality of second holes corresponding to the plurality of first holes; and then forming an air gap between the interlayer insulating layer and the second metal barrier layer pattern including the plurality of second holes by removing the positive photoresist pattern and the negative photoresist pattern.

Embodiments relate to a semiconductor device that can include a lower metal wiring formed over a semiconductor substrate; a first metal barrier layer formed over the lower metal wiring; an interlayer insulating layer formed over the first metal barrier layer; an upper metal wiring formed over the interlayer insulating layer; a contact for electrically connecting the lower metal wiring and the upper metal wiring; a second metal barrier layer pattern having a plurality of holes formed over the upper metal wiring and over the interlayer insulating layer; and an air gap formed between the interlayer insulating layer and the second metal barrier layer pattern including the plurality of holes. In accordance with embodiments, the air gap can be formed in regions between the interlayer insulating layer and the second metal barrier layer pattern that are not occupied by the upper metal wiring

### DRAWINGS

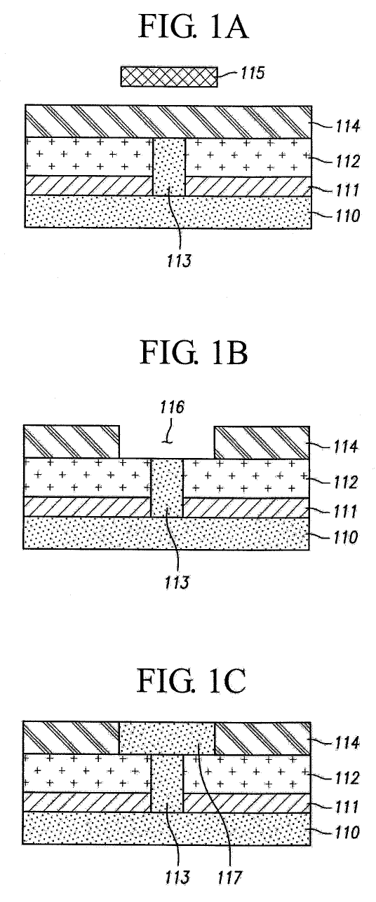

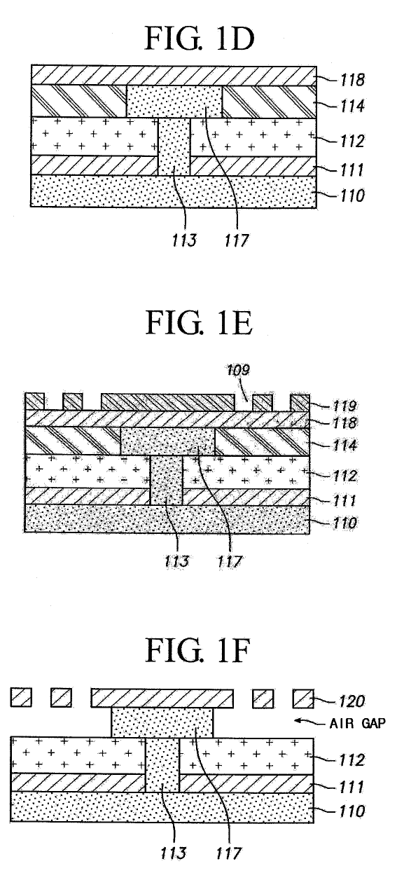

Example FIGS. 1A to 1F illustrate a method for manufacturing a semiconductor device, in accordance with embodiments.

### DESCRIPTION

As illustrated in example FIG. 1A, negative photoresist 114 can be formed on and/or over a lower structure formed on and/or over a semiconductor substrate. The lower structure can include lower metal wiring 110 composed of a metal material such as copper (Cu). First metal barrier layer 111 can be formed on and/or over lower metal wiring 110 and be composed of silicon nitride (SiN). Interlayer insulating layer 112 may be formed between first metal barrier layer 111 and negative photoresist 114 and be composed of a material having a low dielectric constant. Contact 113 extends within first metal barrier layer 111 and interlayer insulating layer 112 and also extends between lower metal wiring 110 and negative photoresist 114 to provides an electrical connection to lower metal wiring 110.

Negative photoresist 114 can be a photosensitive material, an irradiated portion of which is not dissolved during development, contrary to a positive photoresist. Negative photoresist 114 can be coated and formed having a thickness which is 300-500 Å greater than the thickness of lower metal wiring 110 and/or upper metal wiring 117 formed according to the design rule.

Trench mask pattern 115 may then be placed above a region of the negative photoresist 114 where trench 116 is to be formed.

As illustrated in example FIG. 1B, trench 116 can be formed by performing exposure and development processes on negative photoresist 114 using trench mask pattern 115.

As illustrated in example FIG. 1C, upper metal wiring 117 composed of a metal material such as copper (Cu) can then be formed in trench 116. A chemical mechanical polishing (CMP) process can then be performed to planarize the entire surface of negative photoresist 114 including upper metal wiring 117.

As illustrated in example FIG. 1D, second metal barrier layer 118 for forming an air gap can then be formed on and/or over planarized negative photoresist 114 including upper metal wiring 117. Second metal barrier layer 118 can be composed of the same material as first metal barrier layer 111, particularly, SiN. Second metal barrier layer 118 may have a thickness between approximately 700-1000 Å.

As illustrated in example FIG. 1E, a positive photoresist can then be coated on and/or over second metal barrier layer 118. A mask may then be placed above the positive photoresist in order to form positive photoresist pattern 119 having a plurality of dense holes 109 arranged above second metal barrier layer 118 and to the left and right sides of upper metal wiring 117. Holes 109 may each have a diameter of about 160-200 nm.

Positive photoresist pattern 119, including holes 109, can be formed by performing exposure and development processes on positive photoresist using a mask. Specifically, exposure and development processes can be performed on positive photoresist using a KrF light source to form positive photoresist pattern 119 having dense holes.

As illustrated in example FIG. 1F, a reactive ion etch (RIE) process may then be performed on second metal barrier layer 118 using positive photoresist pattern 119 as a mask to define second metal barrier layer pattern 120 having a plurality of dense holes.

The RIE etch process for forming second metal barrier layer pattern 120 may include a first stabilization step, an antireflection layer etch step, a second stabilization step, and a main etch step. These steps may be performed under the following process conditions.

The first stabilization step can be performed under process conditions including a pressure of 45-55 mT applied to a process chamber, injecting O₂ gas at a flow rate of 9-11 sccm, injecting Ar gas at a flow rate of 360-440 sccm, injecting CF₄ gas at a flow rate of 70-80 sccm, and a process time of 55-60 seconds.

The antireflection layer etch step can be performed by forming an antireflection layer as a protective layer for subsequent photolithographic processes on and/or over second metal barrier layer 118. The antireflection layer etch step can be performed under process conditions including a pressure of 45-55 mT applied to a process chamber, an RF power of 1100-1300 W set for upper and lower portions in the chamber, injecting O₂ gas at a flow rate of 9-11 sccm, injecting Ar gas at a flow rate of 360-440 sccm, injecting CF₄ gas at a flow rate of 70-80 sccm, and a process time of 26-30 seconds.

The second stabilization step can be performed under process conditions including a pressure of 170-180 mT applied to a process chamber, injecting Ar gas at a flow rate of 155-165 sccm, injecting CF₄ gas at a flow rate of 75-85 sccm, and a process time of 55-60 seconds.

The main etch step may be performed by forming second metal barrier layer pattern 120 having a plurality of dense holes under process conditions including a pressure of 170-180 mT applied to a process chamber, an RF power of 700-800 W set for the upper portion in the chamber, an RF power of 900-1100 W set for the lower portion in the chamber, injecting Ar gas at a flow rate of 155-165 sccm, injecting CF₄ gas at a flow rate of 75-85 sccm, and a process time of 36-44 seconds.

An ashing process can then be performed to remove positive photoresist pattern 119 that has been used as a mask to form second metal barrier layer pattern 120 having a plurality of dense holes. An ashing process is performed sufficient to also remove negative photoresist 114 and positive photoresist pattern 119. The ashing process can be performed under process conditions including a pressure of 4-5 Torr applied to a process chamber, an RF power of 1450-1550 W set for the chamber, injecting O₂ gas at a flow rate of 300-500 sccm, a process temperature of 23-27° C., and a process time of 150-200 seconds.

In this manner, second metal barrier layer 118 can be etched to form second metal barrier layer pattern 120 having a plurality of dense holes, thereby forming an air gap. This allows a further reduction in the dielectric constant of the interlayer insulating layer, thereby solving the RC delay problem.

The semiconductor device manufactured in accordance with embodiments is advantageous in further reducing the dielectric constant of the interlayer insulating layer by forming a plurality of dense holes and a partial air gap in a metal barrier layer between multilayer metal wirings.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a lower metal wiring over a semiconductor substrate;
forming a first metal barrier layer over the lower metal wiring;
forming an interlayer insulating layer over the first metal barrier layer;
forming a contact extending within the first metal barrier layer and the interlayer insulating layer;
forming a negative photoresist over the interlayer insulating layer and the contact;
forming a trench in a negative photoresist;
forming an upper metal wiring in the trench, wherein the upper metal wiring is electrically connected to the lower metal wiring through the contact;
planarizing the entire uppermost surface of the negative photoresist and the upper metal wiring;
forming a second metal barrier layer over the negative photoresist and the upper metal wiring;
forming a positive photoresist pattern having a plurality of first holes over the second metal barrier layer;
forming a second metal barrier layer pattern having a plurality of second holes corresponding to the plurality of first holes; and then
forming an air gap between the interlayer insulating layer and the second metal barrier layer pattern including the plurality of second holes by removing the positive photoresist pattern and the negative photoresist pattern.

2. The method of claim 1, wherein the lower metal wiring and the upper metal wiring each comprise copper, the first metal barrier layer and the second metal barrier layer each comprise silicon nitride and the interlayer insulating layer comprises a material having a low dielectric constant.

3. The method of claim 2, wherein the second metal barrier layer has a thickness between approximately 700-1000 Å.

4. The method of claim 1, wherein the negative photoresist comprises a photosensitive material having an irradiated portion that is not dissolved during development.

5. The method of claim 1, wherein the negative photoresist is coated and has a thickness which is 300-500 Å greater than the thickness of the lower metal wiring and the upper metal wiring.

6. The method of claim 1, wherein forming the trench comprises:
forming a trench mask pattern above a region of the negative photoresist where the trench is to be formed; and then
performing exposure and development processes on the negative photoresist using the trench mask pattern.

7. The method of claim 1, wherein planarizing the uppermost surface of the negative photoresist and the upper metal wiring is performed using a chemical mechanical polishing process.

8. The method of claim 1, wherein forming the positive photorsist pattern comprises:
forming a positive photoresist over the second metal barrier layer; and then
performing exposure and development processes using a KrF light source on the positive photoresist using a mask.

9. The method of claim 1, wherein the plurality of first holes each have a diameter of about 160-200 nm.

10. The method of claim 1, wherein forming the second metal barrier layer having a plurality of second holes comprises:
performing a reactive ion etch process on the second metal barrier layer using the positive photoresist pattern as a mask.

11. The method of claim 10, wherein performing the reactive ion etch process includes a first stabilization step, an antireflection layer etch step, a second stabilization step, and a main etch step.

12. The method of claim 1, wherein the first stabilization step has a process time of between 55-60 seconds and includes applying a pressure of between 45-55 mT to a process chamber, and injecting into the process chamber O₂ gas at a flow rate of between 9-11 sccm, Ar gas at a flow rate of between 360-440 sccm and CF₄ gas at a flow rate of between 70-80 sccm.

13. The method of claim 1, wherein the antireflection layer etch step comprises forming an antireflection layer as a protective layer for subsequent photolithographic processes on the second metal barrier layer.

14. The method of claim 1, wherein the antireflection layer etch step has a process time of between 26-30 seconds and includes applying a pressure of between 45-55 mT to a process chamber, applying an RF power of between 1100-1300 W for upper and lower portions of the chamber, and injecting into the process chamber O₂ gas at a flow rate of between 9-11 sccm, Ar gas at a flow rate of between 360-440 sccm and CF₄ gas at a flow rate of between 70-80 sccm.

15. The method of claim 1, wherein the second stabilization step has a process time of 55-60 seconds and includes applying a pressure of between 170-180 mT applied to a process chamber, and injecting into the process chamber Ar gas at a flow rate of between 155-165 sccm and CF₄ gas at a flow rate of between 75-85 sccm.

16. The method of claim 1, wherein the main etch step comprises forming the second metal barrier layer pattern having a plurality of second holes.

17. The method of claim 1, wherein the main etch step has a process time of between 36-44 seconds and includes applying a pressure of 170-180 mT applied to a process chamber, applying an RF power of between 700-800 W to the upper portion of the process chamber and an RF power of between 900-1100 W to the lower portion of the chamber, and injecting into the process chamber Ar gas at a flow rate of between 155-165 sccm and CF₄ gas at a flow rate of between 75-85 sccm.

18. The method of claim 1, wherein the positive photoresist pattern, the negative photoresist pattern and the second metal barrier layer pattern are removed using an ashing process.

19. The method of claim 1, wherein the ashing process has a process time of between 150-200 seconds and includes applying a pressure of between 4-5 Torr to a process chamber, applying an RF power of between 1450-1550 W to the process chamber, injecting into the process chamber O₂ gas at a flow rate of between 300-500 sccm, and a process temperature of between 23-27° C.

20. An apparatus comprising:
a lower metal wiring formed over a semiconductor substrate;
a first metal barrier layer formed over the lower metal wiring;
an interlayer insulating layer formed over the first metal barrier layer;
an upper metal wiring formed over the interlayer insulating layer;
a contact for electrically connecting the lower metal wiring and the upper metal wiring;
a second metal barrier layer pattern having a plurality of holes formed over the upper metal wiring and over the interlayer insulating layer; and
an air gap formed between the interlayer insulating layer and the second metal barrier layer pattern including the plurality of holes, wherein the air gap is formed in regions between the interlayer insulating layer and the second metal barrier layer pattern that are not occupied by the upper metal wiring.
